(19) United States
(12) Patent Application Publication
(10) Pub. No.: US 2014/0349435 A1
(43) Pub. Date: Nov. 27, 2014

(54) THERMOELECTRIC SEMICONDUCTOR

(71) Applicants: Junya Murai, Nissin-shi (JP); Yoshinori Okawauchi, Nagoya-shi (JP)

(72) Inventors: Junya Murai, Nissin-shi (JP); Yoshinori Okawauchi, Nagoya-shi (JP)

(73) Assignees: ADMATECHS COMPANY LIMITED, Miyoshi-shi, Aichi (JP); TOYOTA JIDOSHA KABUSHIKI KAISHA, Toyota-shi, Aichi-ken (JP)

(21) Appl. No.: 14/374,657

(22) PCT Filed: Jan. 25, 2013
(86) PCT No.: PCT/IB2013/000084

§ 371 Date: Jul. 25, 2014

(30) Foreign Application Priority Data
Jan. 26, 2012 (JP) 2012-014670

(51) Int. Cl. H01L 35/34; H01L 35/18; H01L 35/16

(52) U.S. Cl. CPC H01L 35/34; H01L 35/16; H01L 35/18
USPC 438/54

(57) ABSTRACT

A thermoelectric semiconductor includes a matrix element that forms a matrix, and a dopant element having an atomic radius that is at least 1.09 times as large as the atomic radius of the matrix element.

### BACKGROUND OF THE INVENTION

1. Field of the Invention

The invention relates to a thermoelectric semiconductor.

2. Description of Related Art

In recent years, in order to reduce carbon dioxide emissions that cause global warming, there has been a steady growth of interest in technology that lowers the proportion of energy obtained from fossil fuels. An example of one such technology is the thermoelectric semiconductor, which can convert unused waste heat energy directly into electrical energy. A thermoelectric semiconductor is a material which is able to convert heat directly into electrical energy without requiring a two-stage process of first converting heat into kinetic energy, then converting the kinetic energy into electrical energy, as in thermal power generation.

Conversion from heat to electrical energy is carried out by utilizing the temperature difference at both ends of a bulk body shaped from the thermoelectric semiconductor. The development of a voltage due to such a temperature difference was discovered by Thomas Johann Seebeck, and is thus called the Seebeck effect. The performance of such a thermoelectric semiconductor is expressed by the figure of merit ZT which is determined by the following formula.

ZT=α²σT/κ(=Pf·T/κ)

Here, α is the Seebeck coefficient of the thermoelectric semiconductor, σ is the electrical conductivity of the thermoelectric semiconductor, and κ is the thermal conductivity of the thermoelectric semiconductor. The term α²σ is collectively referred to as the output factor Pf. Also, because the figure of merit Z has a dimension which is reciprocal to that of the temperature, the ZT obtained by multiplying this Z with the absolute temperature T is a dimensionless value. This ZT is called the dimensionless figure of merit, and is used as an indicator for expressing the performance of the thermoelectric semiconductor.

To enable the wide use of thermoelectric semiconductors, it is desired that their performance be further improved. In turn, as is apparent from the above formula, to improve the performance of the thermoelectric semiconductor, a higher Seebeck coefficient α, a higher electrical conductivity σ and a lower thermal conductivity κ are desired.

However, improving all of these characteristics at the same time is difficult; instead, numerous attempts have been made to improve one or another such characteristic of thermoelectric semiconductors.

Doping, which is the addition of a small amount of an impurity in order to change the properties of a semiconductor, is often carried out in semiconductors. By adding an impurity, it is possible to adjust the concentrations of electrons and holes (carriers), and to regulate in various ways the band structure, physical characteristics, etc. of the forbidden band gap and the like.

For example, Japanese Patent Application Publication No. 10-74986 (JP-10-74986 A) discloses, in the production of PbTe system thermoelectric conversion devices, which are thermoelectric conversion devices that exhibit a high thermoelectric conversion efficiency in intermediate temperature range applications, the use of a p-type PbTe powder material doped with potassium and sodium when obtaining a p-type thermoelectric conversion device.

### SUMMARY OF THE INVENTION

In the conventional art described above, the increase in the electrical conductivity σ is inadequate and the resulting thermoelectric semiconductor has a figure of merit which cannot be regarded as sufficiently high. Hence, the object of the invention is to enable a high electrical conductivity σ to be achieved, and thereby provide a thermoelectric semiconductor having a high figure of merit.

In a first aspect, the invention provides a thermoelectric semiconductor having a matrix element that forms a matrix, and a dopant element having an atomic radius that is at least 1.09 times as large as the atomic radius of the matrix element.

In the foregoing aspect of the invention, the matrix may be formed of a plurality of matrix elements, and the atomic radius of the dopant element may be at least 1.09 times as large as the atomic radius of the matrix element having the highest abundance among the plurality of matrix elements.

Moreover, in the foregoing aspect of the invention, the plurality of matrix elements may include bismuth (Bi), antimony (Sb) and tellurium (Te).

Furthermore, in the foregoing aspect of the invention, the matrix may be a (Bi, Sb)₂Te₃ system.

Additionally, in the foregoing aspect of the invention, the dopant element may be at least one of alkali metal and alkaline earth metal.

Also, in the foregoing aspect of the invention, the dopant element may have a concentration of 10 to 7,000 ppm.

The above aspects of the invention enable a high electrical conductivity σ to be achieved, and thus make it possible to provide a thermoelectric semiconductor having a high figure of merit.

### BRIEF DESCRIPTION OF THE DRAWINGS

Features, advantages, and the technical and industrial significance of exemplary embodiments of the invention will be described below with reference to the accompanying drawings, in which like numerals denote like elements, and wherein:

FIG. 1 is a diagram which schematically shows the lattice-like crystal structure of a thermoelectric semiconductor according to one embodiment of the invention;

FIG. 2 is diagram which schematically shows the layered crystal structure of a thermoelectric semiconductor according to another embodiment of the invention;

FIG. 3 is a diagram which schematically shows α, σ and α²σ in the thermoelectric semiconductor according to still another embodiment of the invention;

FIG. 4 is a diagram which illustrates a method of producing the thermoelectric conductors of Example 1 according to the invention and of a comparative example;

FIG. 5 shows the results of measurements of the Seebeck coefficient α, electrical conductivity σ and output factor Pf for the sodium-doped thermoelectric semiconductor in Example 1 of the invention;

FIG. 6 shows the results of measurements of the Seebeck coefficient α, electrical conductivity σ and output factor Pf for the thermoelectric semiconductors of Example 1 of the invention and the comparative example;

FIG. 7 is a diagram which illustrates a method of producing the thermoelectric semiconductor of Example 2 of the invention;

FIG. 8 shows the results of measurements of the Seebeck coefficient α, electrical conductivity σ and output factor Pf for the potassium-doped thermoelectric semiconductor of Example 2 of the invention;

FIG. 9 is a diagram which illustrates the behavior of carriers in a conventional thermoelectric semiconductor; and

FIG. 10 is a diagram which schematically shows α, σ and α²σ in a conventional thermoelectric semiconductor.

### DETAILED DESCRIPTION OF EMBODIMENTS

The thermoelectric semiconductor according to an embodiment of the invention includes a matrix element that forms a matrix, and a dopant element having an atomic radius that is at least 1.09 times as large as the atomic radius of the matrix element.

The inventor has pondered the reasons why the figure of merit ZT in conventional thermoelectric semiconductors is inadequate and arrived at the following explanation.

In conventional thermoelectric semiconductors, element substitution and doping are carried out in order to increase the carrier concentration and improve the electrical conductivity σ. However, because the different element to be substituted or doped is substituted onto carrier conduction paths, as more substitution or doping is carried out, carrier scattering occurs, lowering the carrier mobility. Hence, even if the carrier concentration is raised, the mobility decreases, and so what improvement does occur in the electrical conductivity σ is not very substantial. As a result, the figure of merit ZT is inadequate.

The reason for this is explained more fully below.

In the field of semiconductors, as a general rule, a substituting element or doping element is often selected from among those elements which, on the periodic table of the elements, are adjacent to the matrix element making up the semiconductor. For example, in silicon semiconductors in which silicon serves as the matrix, a p-type semiconductor is created by incorporating boron as the doping element, and an n-type semiconductor is created by incorporating arsenic as the doping element.

In the field of thermoelectric semiconductors, in Bi₂Te₃ system thermoelectric semiconductors, for example, antimony (Sb), tin (Sn) and indium (In) are used as P-type substituting elements, and selenium (Se) is used as an N-type substituting element. In (Bi,Sb)₂Te₃ system thermoelectric semiconductors, a trace amount of tellurium (Te) is added as the dopant, and in Bi₂(Sb,Te)₃ system thermoelectric semiconductors, a halogen such as iodine (I) is added as the dopant. In PbTe-based thermoelectric semiconductors, sodium (Na) is used as a P-type dopant, and I is used as an N-type dopant. In SiGe-based thermoelectric semiconductors, boron (B) is used as the dopant.

The atomic radii of the elements which form the matrix (matrix elements) and of the substituting elements or doping elements in the above-mentioned thermoelectric semiconductors are as follows.

Bi: 156 picometers (pm); Te: 140 pm; Sb: 140 pm; Pb: 175 pm; Na: 186 pm; Sn: 140 pm; Se: 120 pm; I: 140 pm; B: 90 pm; Si: 210 pm; Ge: 122 pm.

As is apparent from these atomic radii, in conventional thermoelectric semiconductors, the atomic radius of the substituting element or doping element is in each case close in size to or smaller than the atomic radius of the element making up the matrix. An example in which the atomic radii of the matrix element and the substituting element or doping element are close in size is the P-type substituting element In within a Bi₂Te₃ system thermoelectric semiconductor (matrix). The element Bi forming the matrix has an atomic radius of 156 pm, and the substituting element In has an atomic radius of 167 pm. The ratio therebetween is 167/156=1.07. Another example is the P-type dopant Na within a PbTe system thermoelectric semiconductor. The matrix element Pb has an atomic radius of 175 pm, and the dopant Na has an atomic radius of 186 pm. Hence, the ratio therebetween is 186/175=1.06.

In the above thermoelectric semiconductors, the atomic radius of the substituting element or doping element is either close in size to or smaller than the atomic radius of the matrix element in the thermoelectric semiconductor. As a result, an element A which makes up the matrix is easily substituted with a doping element B which is a different element. The doping element B is thus substituted onto carrier conduction paths, which gives rise to carrier scattering and brings about a decrease in carrier mobility.

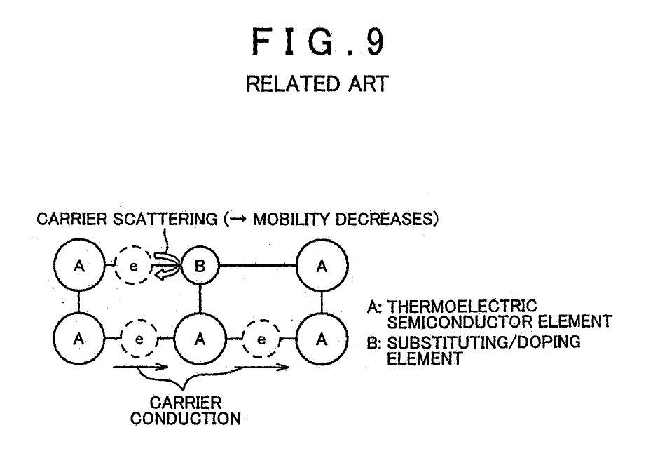

This decrease in mobility is explained in conjunction with FIG. 9. FIG. 9 is a diagram illustrating the behavior of carriers. A is the matrix element in a thermoelectric semiconductor, B is a substituting/doping element, and e is a carrier (electron or hole). In FIG. 9, a portion of the element A which originally made up the matrix of the thermoelectric semiconductor has been substituted with a doping element B. This doping element acts as a carrier supply source; when the doping element is increased, the carrier concentration also increases. At the same time, because this doping element is substituted onto carrier conduction paths, the carriers conducted in are scattered, as a result of which the carrier mobility decreases.

Due to the decrease in carrier mobility, the electrical conductivity σ also decreases and, in turn, the figure of merit ZT of the thermoelectric semiconductor decreases.

First, the decrease in the electrical conductivity σ (S/cm) within the semiconductor is explained. The electrical conductivity σ is calculated as follows:

σ=enμ

where e is the elementary electrical charge (a constant), n is the carrier concentration, and μ is the mobility.

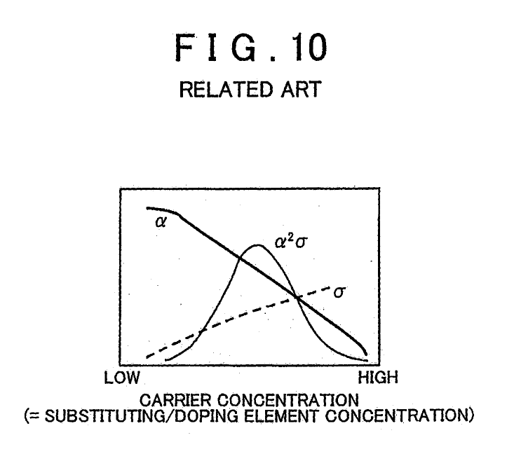

As explained above, when the doping level, i.e., the amount of substitution, is increased, the carrier concentration rises, but carrier scattering also occurs, lowering the mobility. As a result, the electrical conductivity σ does not undergo a very large increase. This is illustrated in FIG. 10.

FIG. 10 is a graph which schematically shows the coefficients for the thermoelectric semiconductor figure of merit—α (Seebeck coefficient), σ (electrical conductivity) and α²σ (output factor)—when the carrier concentration is increased, i.e., when the level of substitution or doping is increased, in a conventional thermoelectric semiconductor.

As shown in FIG. 10, as the carrier concentration increases, the matrix element in the thermoelectric semiconductor decreases and, in turn, α decreases.

Moreover, as shown in FIG. 10, as the carrier concentration is increased, α decreases and σ does not increase as much, as a result of which α²σ is a curve having a peak (a maximum point). That is, α²σ increases at first, then reaches a peak, after which it decreases. Moreover, the peak is not yet sufficiently high.

Here, α²σ is the coefficient of the thermoelectric semiconductor figure of merit ZT. That is, the figure of merit ZT for the thermoelectric semiconductor is proportional to α²σ. Therefore, when the carrier concentration is increased, the figure of merit ZT increases at first. However, upon reaching a peak, it then decreases. Moreover, the peak cannot yet be regarded as sufficiently high. This appears to be the reason why the figure of merit ZT of a conventional thermoelectric semiconductor is insufficient.

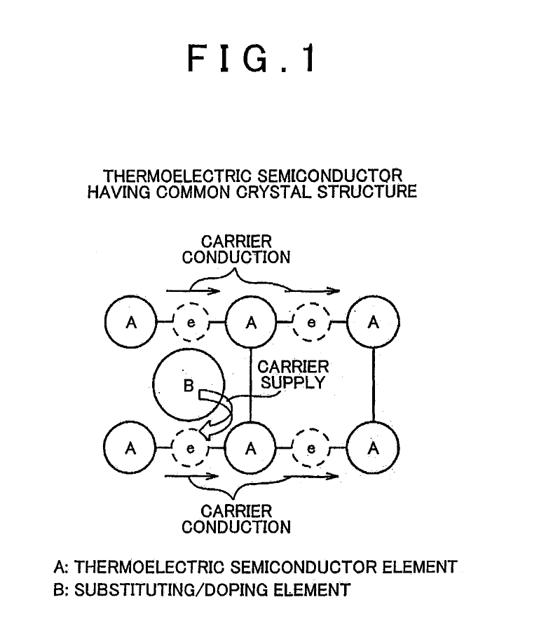

It occurred to the inventor that the figure of merit ZT for the thermoelectric semiconductor might be enhanced by using as the dopant element an element having a larger atomic radius than the matrix element, and more particularly an element having an atomic radius at least 1.09 times as large as the atomic radius of the matrix element. In this case, as shown in FIG. 1, because the doping element B has a large atomic radius, atomic substitution of this element for the matrix element A does not occur. As a result, the frequency of carrier scattering that has occurred in conventional thermoelectric semiconductors due to the substitution of dopant for the matrix element decreases.

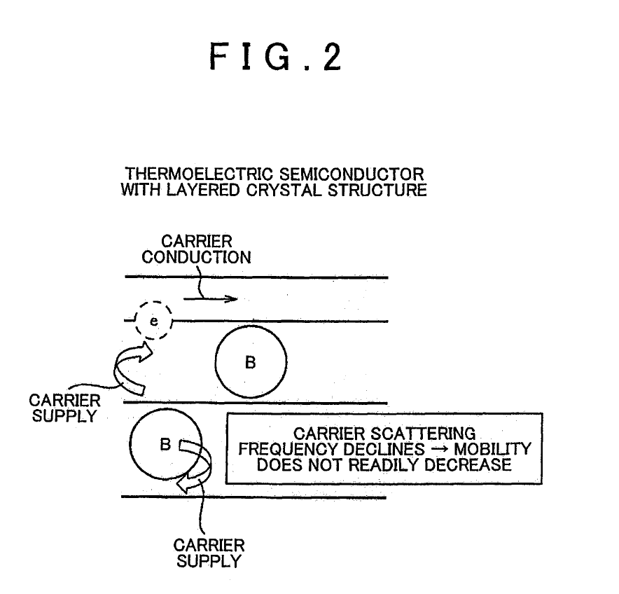

A thermoelectric semiconductor having a common lattice-like crystal structure is schematically shown in FIG. 1, and the fact that substitution by the dopant in such a semiconductor does not occur was explained above. The frequency of carrier scattering similarly declines even in thermoelectric semiconductors having a layered crystal structure, such as (Bi, Sb)₂Te₃ system thermoelectric semiconductors. This fact is explained in conjunction with FIG. 2. FIG. 2 schematically shows a thermoelectric semiconductor having a layered crystal structure. In a layered thermoelectric semiconductor, the matrix element forms into layers, and a plurality of such layers are stacked to form a layered thermoelectric semiconductor. Each layer acts as a carrier conduction path. In FIG. 2, the solid lines (bold lines) represent the respective layers of the layered thermoelectric semiconductor. Because the element added as a dopant has a larger atomic radius than the element making up the layers (matrix element), the dopant element is not substituted for the element making up the layers, and instead is present between the layers. Therefore, the carrier conduction paths remain intact, and the frequency of carrier scattering decreases relative to conventional thermoelectric semiconductors (in which the atomic radius of the dopant is close in size to or smaller than the atomic radius of the matrix element).

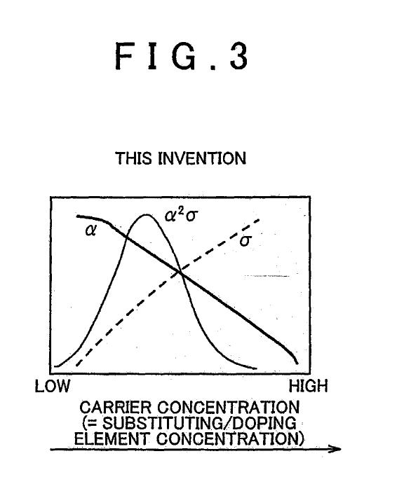

As a result, in the thermoelectric semiconductor of the invention, the carrier mobility is less likely to decrease and, as shown in FIG. 3, the electrical conductivity σ greatly increases compared with a conventional thermoelectric semiconductor shown in FIG. 2. In FIG. 3 also shows α. Here too, in much the same way as in FIG. 10 for a conventional thermoelectric semiconductor, as the carrier concentration increases, the matrix element in the thermoelectric semiconductor decreases, and is accompanied by a decline in α as well.

The value α²σ, which is a factor proportional to the figure of merit ZT, is also shown in FIG. 3. As the carrier concentration is increased, α decreases, but σ undergoes a large increase. As a result, α²σ becomes a curve having a peak that rises considerably. That is, a major improvement in the figure of merit ZT is achieved.

As noted above, by including in a thermoelectric semiconductor both a matrix element forming the matrix and a dopant element having an atomic radius at least 1.09 times as large as the atomic radius of the matrix element, the figure of merit ZT of the resulting thermoelectric semiconductor undergoes a large improvement.

The matrix used in the thermoelectric semiconductor of the invention is not subject to any particular limitation, and may even be formed of a plurality of matrix elements. In cases where the matrix is formed of a plurality of matrix elements, as a general rule, substitution by a dopant element is thought to arise more readily with a matrix element present in a high abundance. Therefore, in order to suppress substitution by the dopant element, it is effective to suppress substitution with the matrix element having a high abundance. To this end, the atomic radius of the dopant element is preferably set to at least 1.09 times the atomic radius of the matrix element having a high abundance. As a result, substitution between the matrix element having a high abundance and the dopant element does not arise, and the frequency of carrier scattering observed in conventional thermoelectric semiconductors decreases.

The plurality of matrix elements desirable for use in the thermoelectric semiconductors of the invention is exemplified by Bi, Sb, Te, Ti, Ni, Sn, Zr, Co, Pb, Si, Ge, Mg and Si. Of these, Bi, Sb and Te are especially preferred as the plurality of matrix elements.

Examples of matrixes desirable for use in the thermoelectric semiconductor of the invention include (Bi,Sb)₂Te₃ systems, (Bi,Sb)₂(Te,Se)₃ systems, TiNiSn systems, ZrNiSn systems, CoSb₃ systems, PbTe systems, SiGe systems and MgSi systems. A (Bi,Sb)₂Te₃ system is especially preferred.

The dopant used in the thermoelectric semiconductor of the invention is not subject to any particular limitation, provided it is an element having an atomic radius at least 1.09 times as large as the atomic radius of the element forming the matrix. The atomic radius of the dopant is more preferably at least 1.1 times, and even more preferably at least about 1.2 times, the atomic radius of the element forming the matrix. This is because, if the atomic radii are close in size, there is an increased possibility that substitution of the matrix element by the dopant element will arise, as a result of which the improvement in the figure of merit may be insufficient.

The dopant used in the thermoelectric semiconductor of the invention may be at least one of alkali metal and alkaline earth metal. This is because, in general, the elements of smaller groups in the same period of the periodic table, such as alkali metals or alkaline earth metals, have large atomic radii.

Specifically, the atomic radii of alkali metal or alkaline earth metal elements are as follows.

| alkali metal elements | alkaline earth metal elements |
|---|---|
| Li: 152 pm | Be, 112 pm |
| Na: 186 pm | Mg: 160 pm |
| K: 227 pm | Ca: 197 pm |
| Rb: 248 pm | Sr: 215 pm |
| Cs: 265 pm | Ba: 222 pm |
| Fr: 260 pm | Ra: 221 pm |

(In the case of Fr and Ra, atomic radius data were not found, and so the values shown are the covalent radii. Generally, the atomic radius of an element is slightly larger than the covalent radius.)

The dopant concentration used in the thermoelectric semiconductor of the invention may be from 10 to 7,000 ppm, and is preferably from 50 to 5,000 ppm. At a dopant concentration lower than this range, the effects of doping, such as the action as a carrier supply source, are not obtained. On the other hand, at a dopant concentration higher than this range, the element forming the matrix of the thermoelectric semiconductor decreases and the Seebeck coefficient becomes smaller, as a result of which a sufficient improvement in the figure of merit may not be achieved.

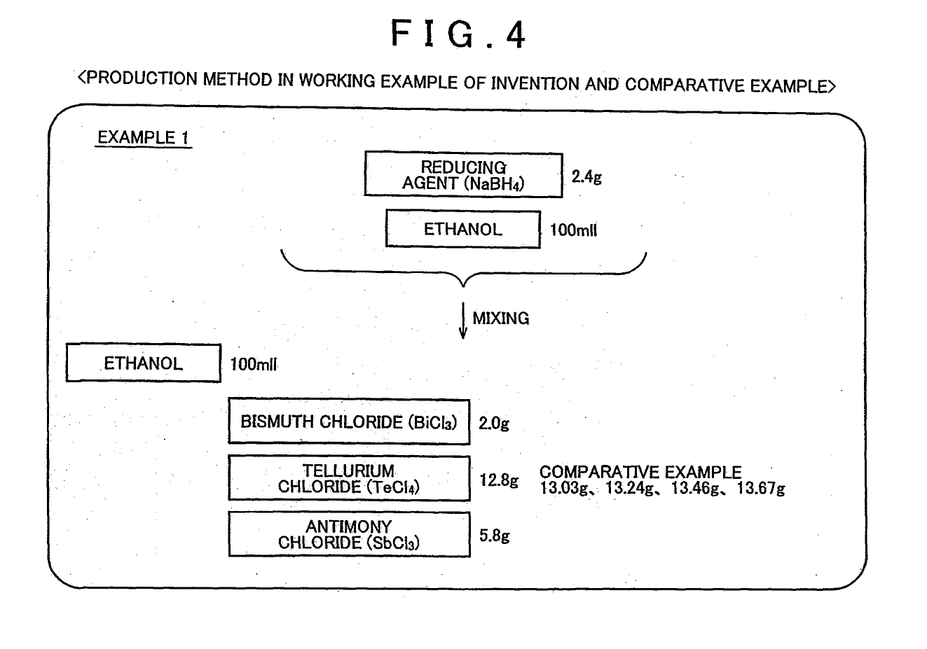

A method of fabricating the thermoelectric semiconductor of the invention is described while referring to FIG. 4. By adding dropwise an ethanol solution of the reducing agent NaBH₄ to a bismuth chloride, tellurium chloride and antimony chloride-containing slurry (wherein ethanol serves as the solvent), which is an example of a starting material for a thermoelectric semiconductor matrix, a thermoelectric semiconductor precursor to which has been added sodium as one example of a dopant is chemically reduced and synthesized. Next, the synthesized precursor-containing ethanol slurry is filtered and rinsed with water, then is filtered and rinsed with ethanol. At this time, the amount of water used for filtration and rinsing is variously adjusted, thereby adjusting the Na concentration within the sample. Next, alloying can be effected by carrying out hydrothermal treatment in a closed pressure vessel such as a closed autoclave at a temperature of from 200 to 400° C. for a period of at least 10 hours, such as 10 to 100 hours, and especially about 24 to 100 hours. Next, drying is typically carried out in a non-oxidizing atmosphere, such as a nitrogen or other inert atmosphere, thereby yielding a thermoelectric semiconductor precursor in the form of a powder. In addition, the thermoelectric semiconductor precursor in powder form is spark plasma sintered (SPS) at a temperature of 300 to 600° C., thereby giving a (BiSb)₂Te₃ sintered body.

The salt serving as the starting material for the thermoelectric semiconductor matrix may be a salt of one or more elements selected from among Bi, Sb, Ag, Pb, Ge, Cu, Sn, As, Se, Te, Fe, Mn, Co and Si, such as a salt of Bi, Sb, Te, Co, Ni, Sn or Ge; or may be a halide of any of the above elements, such as a chloride, fluoride or bromide. Preferred examples include chlorides, sulfates and nitrates.

The solvent for obtaining the above slurry is not subject to any particular limitation, provided it is capable of uniformly dispersing, and especially dissolving, the starting material for the thermoelectric semiconductor matrix. Illustrative examples include methanol, ethanol, isopropanol, dimethylacetamide and N-methylpyrrolidone. The use of an alcohol such as methanol or ethanol is preferred.

The above reducing agents are not subject to any particular limitation, provided they are capable of reducing the salt serving as the starting material for the thermoelectric semiconductor matrix. Illustrative examples include tertiary phosphines, secondary phosphines and primary phosphines, hydrazines, hydroxyphenyl compounds, hydrogen, hydrides, boranes, aldehydes, reducing halides and polyfunctional reductants. Of these, one or more substances such as an alkali borohydride (e.g., sodium borohydride, potassium borohydride, lithium borohydride) may be used.

This reducing agent is capable of serving as the dopant source, with the use of a reducing agent containing the dopant element being convenient. However, it is also possible to admix the dopant separately. For example, the hydroxides, halides, sulfates, nitrates or the like of other dopant elements may be added; in cases where potassium is to be used as the dopant, KOH may be added to the above slurry. Alternatively, in cases where tellurium is to be used as the dopant, the mixing amount of the tellurium chloride used as one of the salts serving as the starting materials for the thermoelectric semiconductor matrix may be adjusted.

The above-mentioned spark plasma sintering may be carried out using a SPS system equipped with punches (top and bottom), electrodes (top and bottom), a die and a pressurizing unit. At the time of sintering, it is possible either to isolate only the sintering chamber of the SPS system from the outside air and place it under an inert sintering atmosphere, or to enclose the entire system in a housing and thereby place it under an inert atmosphere.

### EXAMPLE 1

A Na-doped thermoelectric semiconductor was fabricated in accordance with the flow chart shown in FIG. 4.

### Preparation of Starting Material Slurry:

A slurry was prepared by mixing the following starting materials in 100 mL of ethanol.

### Matrix Starting Materials

bismuth chloride (BiCl₃), 2.0 g
tellurium chloride (TeCl₄), 12.8 g
antimony chloride (SbCl₃), 5.8 g

### Reduction:

A solution of 2.4 g of NaBH₄ as the reducing agent dissolved in 100 mL of ethanol was added dropwise to the above starting material slurry. The resulting ethanol slurry containing nanoparticles that precipitated out due to reduction was filtered and rinsed with 500 to 5,000 mL of water, then filtered and rinsed again with 300 mL of ethanol. The amount of water used at this time was variously adjusted, thereby adjusting the Na concentration within the sample.

### Heat Treatment (Alloying):

Next, the slurry was charged into a closed autoclave and subjected to 48 hours of hydrothermal treatment at 240° C., thereby inducing alloying. Next, drying was carried out in a N₂ gas flow atmosphere, and a powder was recovered.

### Sintering

The recovered powder was spark plasma sintered at 350° C., thereby giving a thermoelectric semiconductor having a matrix formed of (Bi,Sb)₂Te₃ and doped with, as the dopant, Na (atomic radius, 186 pm), which has a much larger atomic radius than the elements Bi, Sb and Te forming the matrix.

### Measurement of Physical Properties:

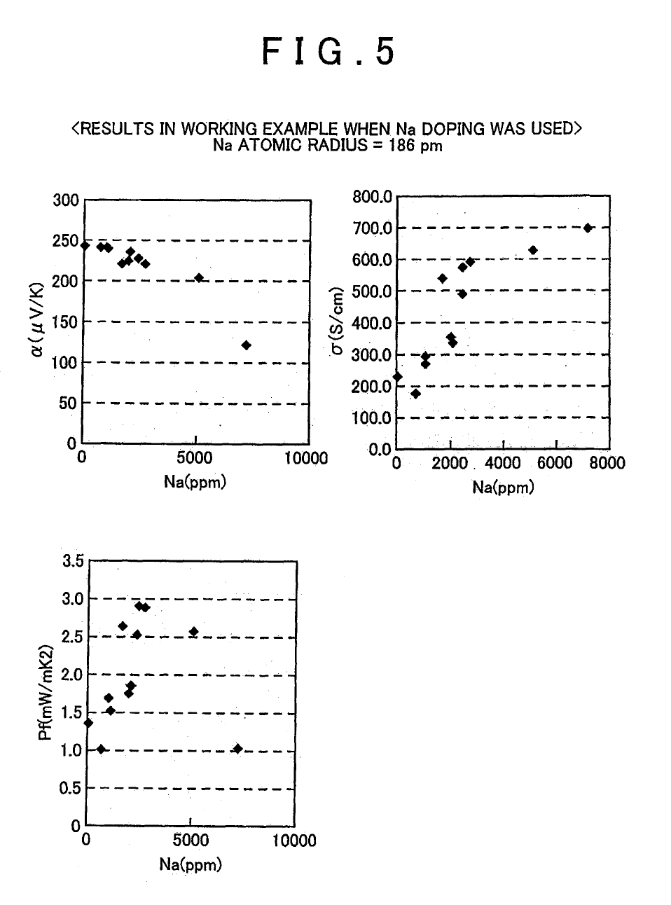

The Seebeck coefficient α, electrical conductivity σ and output factor Pf of the resulting Na-doped thermoelectric semiconductor were measured. The results are shown in FIG. 5. The methods of measurement are described below.

### 1. Measurement of Seebeck Coefficient α

The Seebeck coefficient was measured using a ZEM system (ULVAC-RIKO, Inc.). That is, a thermocouple wire was pressed against a test piece cut from part of the thermoelectric semiconductor, a temperature difference was imparted to the test piece within a temperature-programmed oven, and the Seebeck coefficient was determined by measuring the thermoelectromotive force generated at that time. The Seebeck coefficient was measured by 3-point fitting of ΔV/ΔT.

### 2. Measurement of Electrical Conductivity σ

The electrical resistivity was measured by the 4-probe method using a ZEM system manufactured by Ulvac-Riko, Inc.

### 3. Computation of Output Factor Pf

Because the output factor Pf can be determined as α²σ, this was calculated by multiplying together the measured values for the above-described Seebeck coefficient α and the electrical conductivity σ. As shown in FIG. 5, the electrical conductivity σ rose markedly as the Na concentration increased. This was accompanied by marked rise in the output factor Pf as well. However, at a Na concentration of 7,000 ppm and above, the Seebeck coefficient α decreased, as a result of which the output factor Pf also decreased.

### COMPARATIVE EXAMPLE

A thermoelectric semiconductor was fabricated using Te (atomic radius, 140 pm) instead of Na (atomic radius, 186 pm) as the dopant.

Aside from setting the amount of tellurium chloride (TeCl₄) serving as the matrix feedstock to 13.03 g, 13.24 g, 13.46 g or 13.67 g, Te-doped thermoelectric semiconductors were obtained by the same method as in Example 1.

### Measurement of Physical Properties:

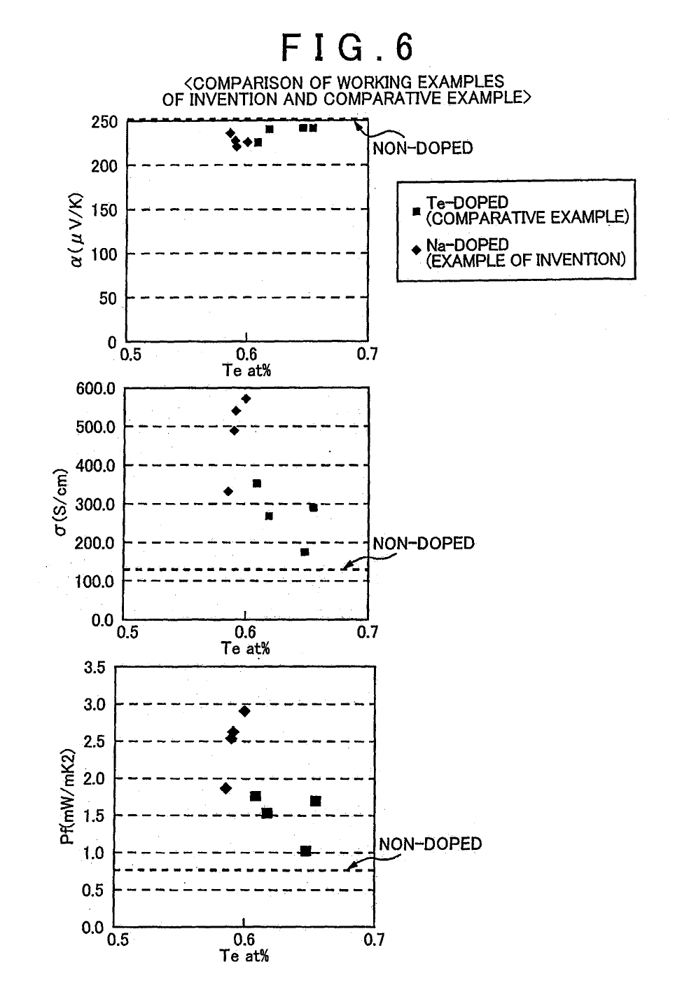

The Seebeck coefficient α, electric conductivity σ and output factor Pf of the resulting Te-doped thermoelectric semiconductor were measured. The results are shown in FIG. 6. FIG. 6 also shows the physical properties of the Na-doped thermoelectric semiconductor of Example 1. As shown in FIG. 6, compared with the Te-doped thermoelectric semiconductor of the comparative example, the electrical conductivity σ in the Na-doped thermoelectric semiconductor of Example 1 is much improved. This was accompanied by a marked rise in the output factor Pf as well.

### EXAMPLE 2

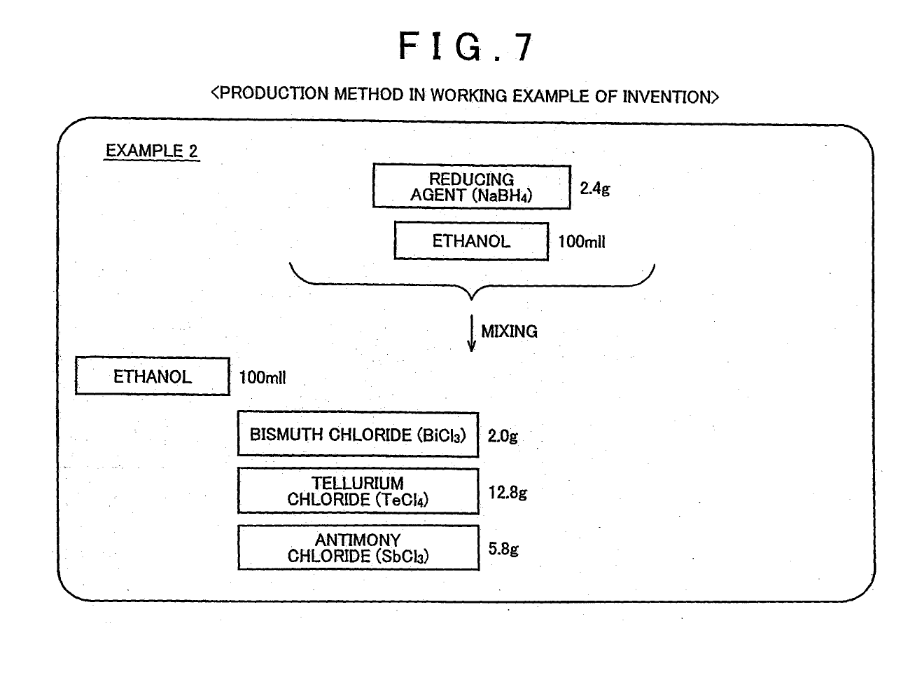

A K-doped thermoelectric semiconductor was fabricated in accordance with the flow chart shown in FIG. 7.

### Preparation of Feedstock Slurry:

A slurry was prepared by mixing the following starting materials into 100 mL of ethanol.

### Matrix Starting Materials

bismuth chloride (BiCl₃), 2.0 g
tellurium chloride (TeCl₄), 12.8 g
antimony chloride (SbCl₃), 5.8 g

### Reduction:

A solution of 2.4 g of NaBH₄ as the reducing agent dissolved in 100 mL of ethanol was added dropwise to the above starting material slurry. The resulting ethanol slurry containing nanoparticles that precipitated out due to reduction was filtered and rinsed with 5,000 mL of water, then filtered and rinsed again with 300 mL of ethanol.

### Dopant (K) Addition:

The dopant element K was added in the form of KOH to the above nanoparticle-containing ethanol slurry in the range of 0.05 to 0.3 g according to the doping level.

### Heat Treatment (Alloying):

The slurry was then charged into a closed autoclave and subjected to 48 hours of hydrothermal treatment at 240° C., thereby inducing alloying. Next, drying was carried out in a N₂ gas flow atmosphere, and a powder was recovered.

### Sintering

The recovered powder was spark plasma sintered at 350° C., thereby giving a thermoelectric semiconductor having a matrix formed of (Bi,Sb)₂Te₃ and doped with, as the dopant, K (atomic radius, 227 pm), which has a much larger atomic radius than the elements Bi, Sb and Te forming the matrix.

### Measurement of Physical Properties:

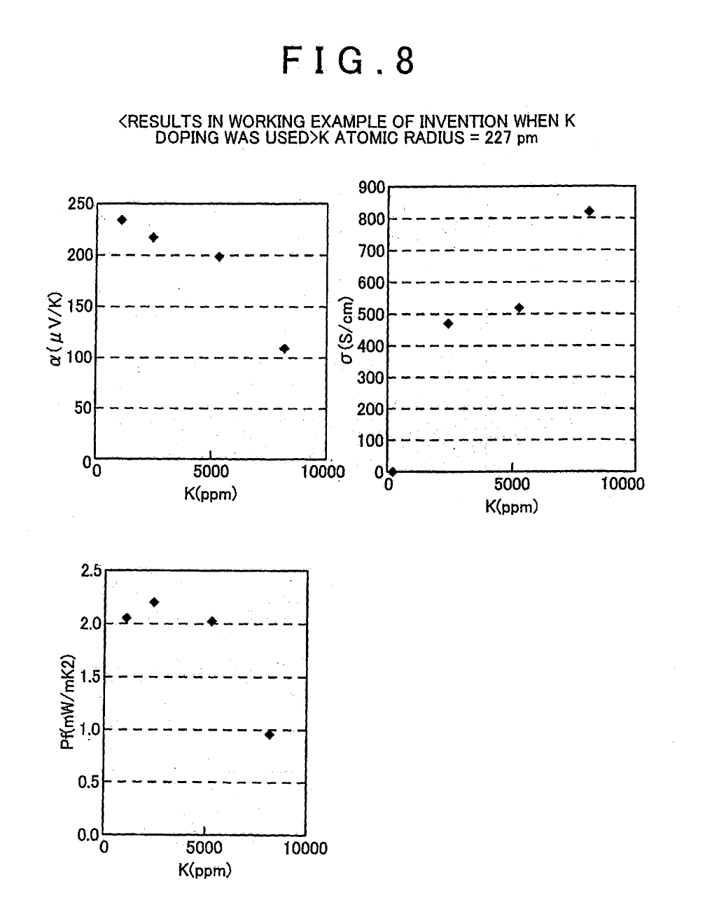

The Seebeck coefficient α, electrical conductivity σ and output factor Pf of the resulting K-doped thermoelectric semiconductor were measured. The results are presented in FIG. 8. As shown in FIG. 8, the electrical conductivity σ rose markedly as the K concentration became higher. This was accompanied by a marked rise in the output factor Pf as well. However, at Na concentrations of 7,000 ppm and above, the Seebeck coefficient α decreased, as a result of which the output factor Pf also decreased. These results were similar to those obtained with Na doping, indicating that the effects of K doping are similar to those of Na doping. Accordingly, on the basis also of the results obtained for the Te-doped thermoelectric semiconductor of the comparative example, it was demonstrated that in thermoelectric semiconductors which use as the dopant an element having a larger atomic radius than the elements making up the matrix, the electrical conductivity is increased and, in turn, the figure of merit is also increased.

1-6. (canceled)

7. A method of fabricating a thermoelectric semiconductor that includes a matrix element that forms a matrix and a dopant element, comprising:
using as the dopant element an element having a larger atomic radius than the matrix element,
wherein the dopant element has an atomic radius at least 1.09 times as large as the atomic radius of the matrix element.

8. The method of fabricating the thermoelectric semiconductor according to claim 7, wherein the matrix is a (Bi, Sb)₂Te₃ system.

9. The method of fabricating the thermoelectric semiconductor according to claim 7, further comprising:
chemically reducing and synthesizing a semiconductor precursor to which has been added the dopant element;
filtering and rinsing the synthesized semiconductor precursor;
alloying the synthesized semiconductor precursor by carrying out hydrothermal treatment;
drying the synthesized semiconductor precursor in a non-oxidizing atmosphere; and
sintering the synthesized semiconductor precursor.
